(19) United States
(12) Patent Application Publication
(10) Pub. No.: US 2010/0055922 A1
(43) Pub. Date: Mar. 4, 2010

(54) METHOD FOR FABRICATING SEMICONDUCTOR DEVICE

(76) Inventors: Tae-Hyoung Kim, Gyeonggi-do (KR); Jun-Hyeub Sun, Gyeonggi-do (KR); Sang-Oh Lee, Gyeonggi-do (KR)

Correspondence Address: IP & T Law Firm PLC, 7700 Little River Turnpike, Suite 207, Annandale, VA, 22003, US

(21) Appl. No.: 12/491,494

(22) Filed: Jun. 25, 2009

(30) Foreign Application Priority Data
Aug. 29, 2008 (KR) 10-2008-0085108

(51) Int. Cl. H01L 21/306

(52) U.S. Cl. 438/745; 257/E21.219

(57) ABSTRACT

A method for fabricating a semiconductor device improves the variation in critical dimensions of neighboring patterns when employing a negative SPT process. The method includes forming an etch stop layer on an etch target layer, forming a first hard mask pattern on the etch stop layer, forming a spacer pattern on a sidewall of the first hard mask pattern, forming a second hard mask layer on an entire surface of a resultant structure including the spacer pattern, forming a second hard mask pattern by etching the second hard mask layer up to a height of the first hard mask pattern, removing the spacer pattern, and forming a pattern by etching the etch stop layer and the etch target layer using the first and the second hard mask patterns as an etch barrier.

### CROSS-REFERENCE TO RELATED APPLICATIONS

The present invention claims priority of Korean patent application number 10-2008-0085108, filed on Aug. 29, 2008, the disclosure of which is incorporated herein by reference in its entirety.

### BACKGROUND OF THE INVENTION

The present invention relates to semiconductor fabricating technology, and more particularly, to a method for fabricating a pattern of a semiconductor device using spacer pattern technology (SPT).

In the development of a semiconductor device, the miniaturization of a pattern is an important factor in enhancing a yield. For the miniaturization, a mask process requires even a smaller size. Thus, a photoresist pattern using an argon fluoride (ArF) exposure source is introduced in a semiconductor device of sub-40 nm.

However, as the miniaturization continuously progresses, a relatively finer pattern is required. Thus, the photoresist pattern using the ArF exposure source also reaches its limitation.

Therefore, new patterning technology is required in both of a dynamic random access memory (DRAM) device and a nonvolatile memory device. For this purpose, a spacer pattern technology (SPT) process is introduced. The SPT process is classified into a positive type and a negative type. In case of the negative type SPT process, there is the variation in critical dimensions of neighboring patterns.

The negative type SPT process will be described in detail with reference to FIGS. 1A to 1F.

FIGS. 1A to 1F illustrate cross-sectional views of a method for fabricating a conventional semiconductor device.

Referring to FIG. 1A, an etch target layer 12, a first hard mask layer 13, a second hard mask layer 14, a silicon oxynitride layer 15 and an anti-reflection layer 16 are formed on a substrate 11.

Then, a photoresist pattern 17 is formed on the anti-reflection layer 16. At this point, the etch target layer 12 includes an oxide layer; the first hard mask layer 13 includes a polysilicon layer; and the second hard mask layer 14 includes an amorphous carbon layer.

Referring to FIG. 1B, the anti-reflection layer 16 and the silicon oxynitride layer 15 are etched using the photoresist pattern 17 as an etch barrier and the second hard mask layer 14 is etched using the etched silicon oxynitride layer as an etch barrier.

Subsequently, a first hard mask pattern 13A is formed by etching the first hard mask layer 13 using the etched second hard mask layer as an etch barrier. At this time, the etch target layer 12 is etched as much as a certain thickness to reduce a height difference between the first hard mask pattern 13A and a subsequent third hard mask pattern, thereby forming a partially etched etch target layer 12A.

Referring to FIG. 1C, a spacer layer 18 is formed along an entire surface of a resultant structure including the first hard mask pattern 13A.

A third hard mask layer 19 is formed on the spacer layer 18 to fill spaces between neighboring first hard mask patterns 13A.

Referring to FIG. 1D, the third hard mask pattern 19A is formed by partially etching the third hard mask layer 19.

Referring to FIG. 1E, a portion of the spacer layer 18 that is disposed between the first hard mask pattern 13A and the third hard mask pattern 19A is etched to expose the partially etched etch target layer 12A. Reference numeral 18A represents spacers formed by etching the spacer layer 18.

Referring to FIG. 1F, an etch target layer pattern 12B is formed by etching the partially etched etch target layer 12A using the first and the third hard mask patterns 13A and 19A as an etch barrier.

As described above, it is possible to achieve a relatively fine pattern, which is not implemented by a photoresist pattern, by performing the negative type SPT process.

However, the prior art has a difficulty in determining an etch target in the process of partially etching the etch target layer 12 when forming the first hard mask pattern 13A, so that the etch target layer 12 is not etched up to an exact depth and thus a device characteristic is deteriorated.

Moreover, in the process of forming the third hard mask pattern 19A, the first hard mask pattern 13A is protected by the spacer layer 18, whereas there occurs a height difference between the first hard mask pattern 13A and the third hard mask pattern 19A as the third hard mask pattern 19A is continuously etched. This height difference causes the variation in critical dimensions of neighboring patterns.

Further, in the process of etching the portion of the spacer layer 18 that is disposed between the first and the third hard mask patterns 13A and 19A, the first and the third hard mask patterns 13A and 19A are partially lost by the dry etching. Herein, if the amount of the loss of the first hard mask pattern 13A is different from that of the third hard mask pattern 19A, the height difference between the first hard mask pattern 13A and the third hard mask pattern 19A becomes a concern.

### SUMMARY OF THE INVENTION

Embodiments of the present invention are directed to providing a method for fabricating a semiconductor device, capable of improving the variation in critical dimensions of neighboring patterns when employing a negative SPT process.

In accordance with an aspect of the present invention, there is provided a method for fabricating a semiconductor device, the method including: forming an etch stop layer on an etch target layer; forming a first hard mask pattern on the etch stop layer; forming a spacer pattern on a sidewall of the first hard mask pattern; forming a second hard mask layer on an entire surface of a resultant structure including the spacer pattern; forming a second hard mask pattern by etching the second hard mask layer up to a height of the first hard mask pattern; removing the spacer pattern; and forming a pattern by etching the etch stop layer and the etch target layer using the first and the second hard mask patterns as an etch barrier.

The first and the second hard mask patterns may be formed of the same material and include polysilicon.

The etch stop layer may be formed of a material having selectivity to the first and the second hard mask pattern and include a nitride layer.

The spacer pattern may include an oxide layer and the oxide layer may include a tetra ethyle ortho silicate (TEOS) oxide layer.

Forming the spacer pattern may include forming a spacer layer along a top surface of a resultant structure including the first hard mask pattern and etching the spacer layer to thereby form the spacer pattern.

Etching the spacer layer may be performed using an oxygen gas and at least one of C₄F₈, CHF₃, CH₂F₂, C₄F₆ and a combination thereof.

Forming the second hard mask pattern may be performed through an etch-back process or a chemical mechanical polishing process.

Removing the spacer pattern may be performed through a wet etching process and the wet etching process may be performed using a buffered oxide etchant (BOE) or HF.

### BRIEF DESCRIPTION OF THE DRAWINGS

FIGS. 1A to 1F illustrate cross-sectional views of a method for fabricating a conventional semiconductor device.

FIGS. 2A to 2F illustrate cross-sectional views of a method for fabricating a semiconductor device in accordance with an embodiment of the present invention.

FIGS. 3A to 3I illustrate cross-sectional views of a method for fabricating a semiconductor device in accordance with a detailed embodiment of the present invention.

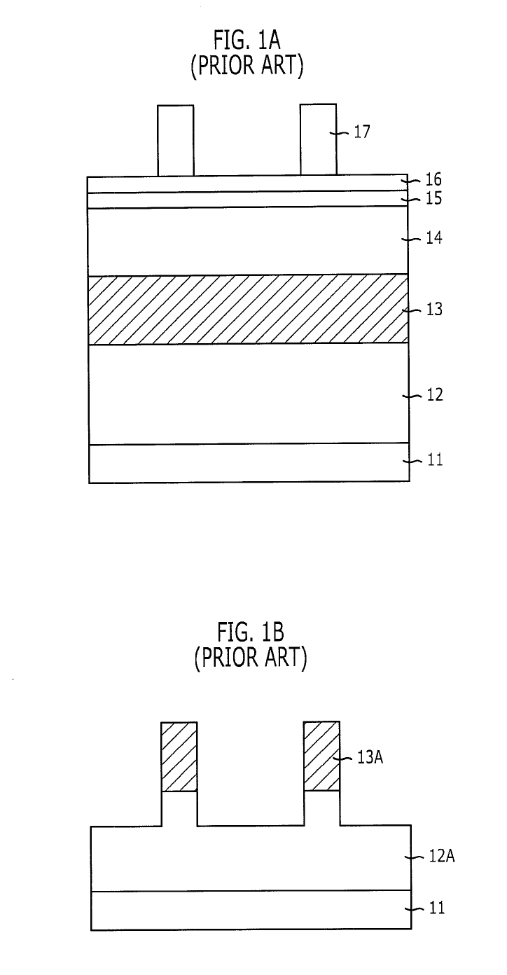

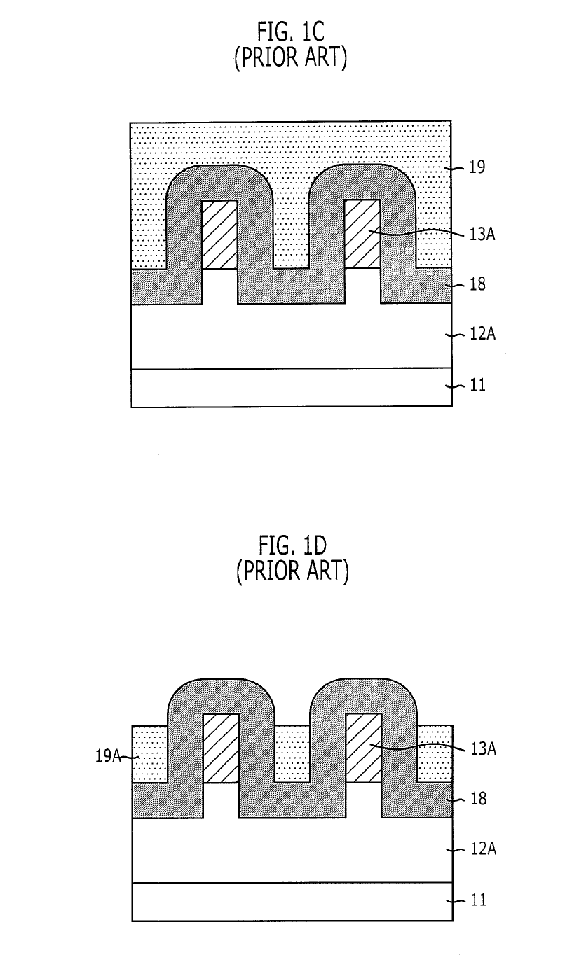

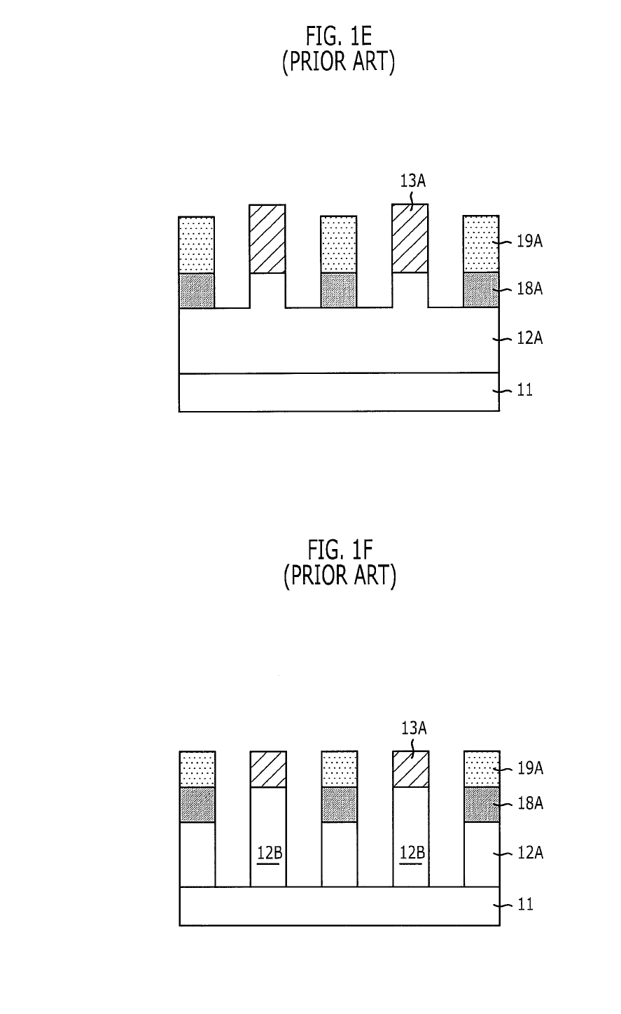

### DESCRIPTION OF SPECIFIC EMBODIMENTS

Other objects and advantages of the present invention can be understood by the following description, and become apparent with reference to the embodiments of the present invention. In the figures, the dimensions of layers and regions may be exemplary and may not be exact. Like reference numerals refer to like elements throughout. It will also be understood that when a layer, a film, a region or a plate is referred to as being ‘on’ another one, it can be directly on the other one, or one or more intervening layers, films, regions or plates may also be present.

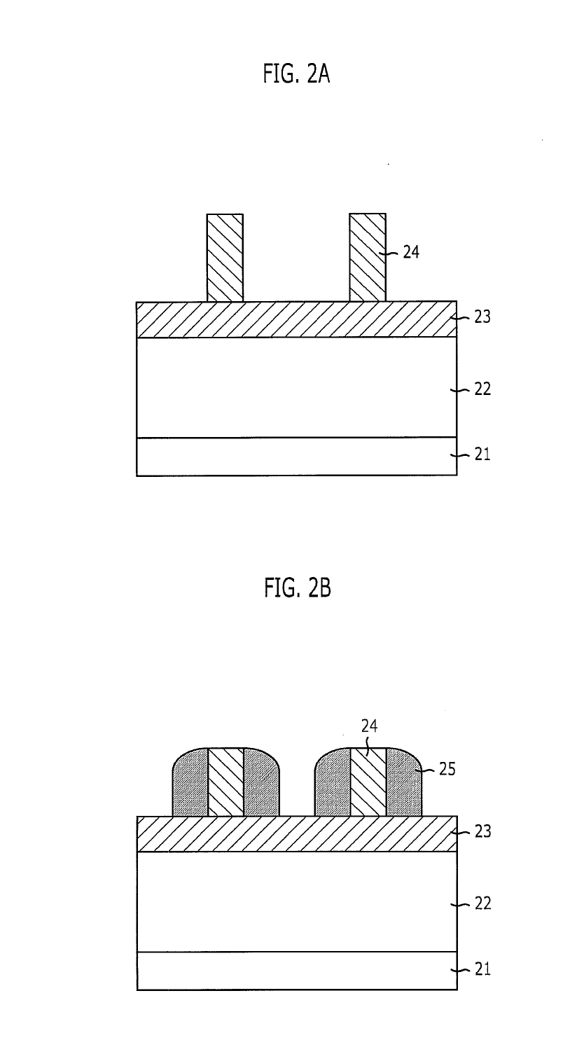

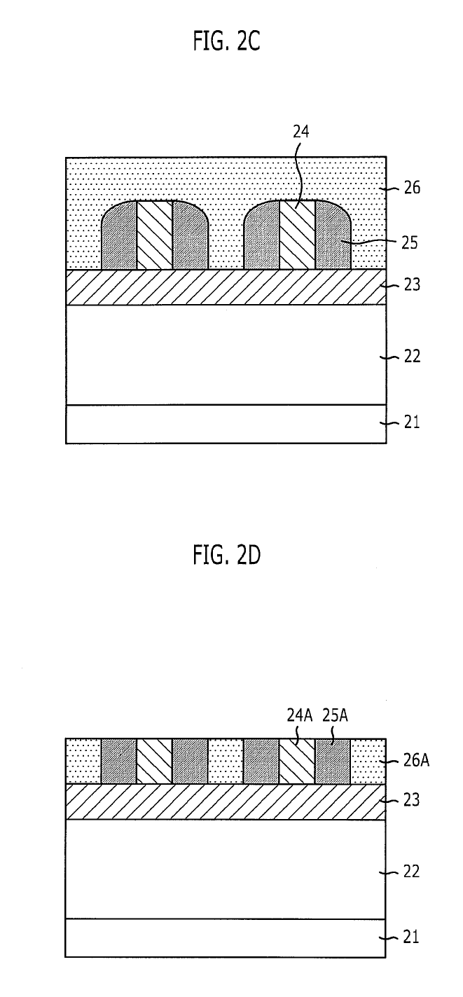

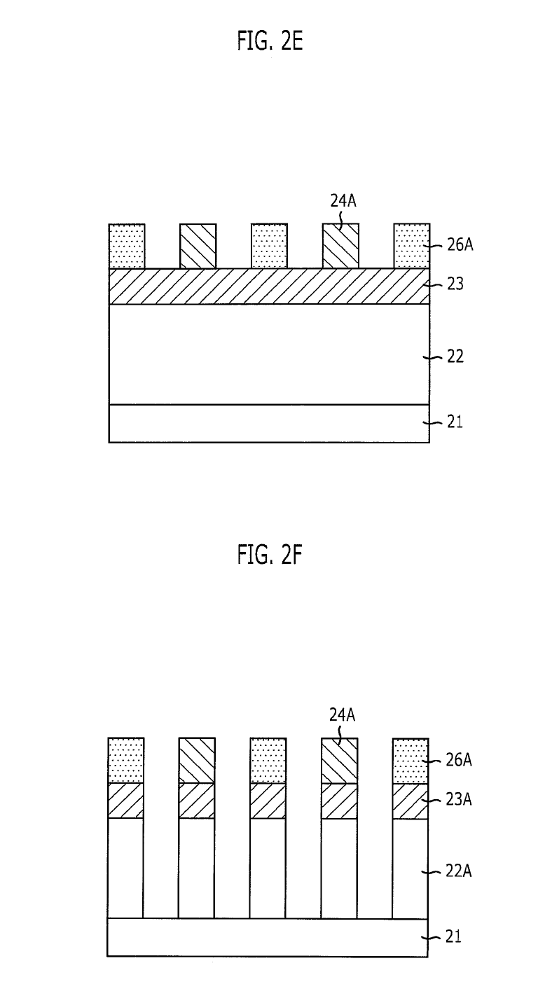

FIGS. 2A to 2F illustrate cross-sectional views of a method for fabricating a semiconductor device in accordance with an embodiment of the present invention.

Referring to FIG. 2A, an etch target layer 22 is formed on a substrate 21. The substrate 21 may include a silicon substrate employed in a process of fabricating a DRAM device or a nonvolatile memory device. The etch target layer 22 is a layer where a pattern is to be formed through a subsequent SPT process and may include an oxide layer. Herein, the oxide layer may include a tetra ethyle ortho silicate (TEOS) oxide layer, especially a plasma enhanced TEOS (PE-TEOS) oxide layer.

Then, an etch stop layer 23 is formed on the etch target layer 22. The etch stop layer 23 is provided to prevent the loss of the etch target layer 22 and may be formed of a material having selectivity to the etch target layer 22 and a subsequent first hard mask pattern 24. The etch stop layer 23 may include a nitride layer. Further, the etch stop layer 23 is formed to have a thickness that is required to sufficiently perform an etch stop function in a subsequent process. For instance, the etch stop layer 23 may have a thickness of approximately 20 Å to approximately 500 Å.

The first hard mask pattern 24 is formed on the etch stop layer 23. The first hard mask pattern 24 is used as an etch barrier in a subsequent process of forming patterns. Since a gap between neighboring first hard mask patterns 24 is wide, the first hard mask pattern 24 is easily formed without being limited by the resolution in an exposure process of a photoresist layer to form the first hard mask pattern 24. The first hard mask pattern 24 may be formed of a material having selectivity to the etch stop layer 23 and include a polysilicon layer.

Referring to FIG. 2B, a spacer pattern 25 is formed on a sidewall of the first hard mask pattern 24. The spacer pattern 25 is formed by forming a spacer layer along a step of a resultant structure including the first hard mask pattern 24 and then etching the spacer layer. The spacer pattern 25 includes an oxide layer and the oxide layer includes a TEOS oxide layer. Particularly, the TEOS oxide layer includes a low pressure TEOS (LP-TEOS) oxide layer.

In case the spacer pattern 25 is formed of the oxide layer, the etching process to form the spacer pattern 25 may be performed using a gas for etching the oxide layer, especially an oxygen gas and one selected from a group comprising C₄F₈, CHF₃, CH₂F₂, C₄F₆ and a combination thereof. Further, each gas may be added with a flow of approximately 4 sccm to approximately 500 sccm. The etching process to form the spacer pattern 25 may be performed for approximately 10 seconds to approximately 100 seconds.

Therefore, the loss of the etch target layer 22 is prevented by the etch stop layer 23 formed of the nitride layer when forming the spacer pattern 25 including the oxide layer.

Referring to FIG. 2C, a second hard mask layer 26 is formed on an entire surface of a resultant structure including the spacer pattern 25. The second hard mask layer 26 serves as an etch barrier together with the first hard mask pattern 24 in a subsequent process of forming patterns. The second hard mask layer 26 may be formed of the same material as that of the first hard mask pattern 24. That is, the second hard mask layer 26 may include a polysilicon layer.

The second hard mask layer 26 may be formed to have a thickness greater than a height of the spacer pattern 25 to sufficiently fill spaces between neighboring spacer patterns 25.

Referring to FIG. 2D, a second hard mask pattern 26A is formed by etching or polishing the second hard mask layer 26 up to the same height as that of the first hard mask pattern 24.

In order to form the second hard mask pattern 26A, it is preferable to perform an etch-back process or a chemical mechanical polishing (CMP) process.

Particularly, the second hard mask pattern 26A has the same height as that of the first hard mask pattern 24. The second hard mask pattern 26A has a vertical profile. That is, in case the spacer pattern 25 has an inclined profile at its top surface by the etching process, the second hard mask pattern 26A having the vertical profile is formed by additionally etching the second hard mask layer 26 buried in a plane that corresponds to the inclined profile. When forming the second hard mask pattern 26A, upper portions of the first hard mask pattern 24 and the spacer pattern 25 may be partially etched up to a top surface of the second hard mask pattern 26A.

Accordingly, the partially etched first and the second hard mask patterns 24A and 26A and the partially etched spacer pattern 25A have a vertical profile.

When forming the second hard mask pattern 26A, since the spacer pattern 25 is formed on the sidewall of the first hard mask pattern 24 and the first hard mask pattern 24 disposed between neighboring spacer patterns 25 is exposed, only the second hard mask layer 26 is additionally etched or a height difference between the first and the second hard mask patterns 24 and 26A is prevented/reduced. Therefore, the variation in critical dimensions of neighboring patterns that is caused by the height difference is improved.

Moreover, since there is no height difference, the etch target layer 22 is not required to be further etched in FIG. 2A and the loss of the etch target layer 22 is prevented by forming the etch stop layer 23 on the etch target layer 22.

Referring to FIG. 2E, the partially etched spacer pattern 25A disposed between the partially etched first and the second hard mask patterns 24A and 26A is removed. The partially etched spacer pattern 25A may be removed through a wet etching process. In case the spacer pattern 25 includes the oxide layer, the wet etching process may be performed using a buffered oxide etchant (BOE) or HF.

Therefore, the partially etched first and the second hard mask patterns 24A and 26A remain as being separated from each other as much as a width of the partially etched spacer pattern 25A.

Since the partially etched spacer pattern 25A is removed through the wet etching process not a dry etching process, the removing process is simplified and the loss of underlying layers is prevented. Furthermore, the loss of the etch target layer 22 is prevented when removing the partially etched spacer pattern 25A by forming the etch stop layer 23 having selectivity on the etch target layer 22 formed of the oxide layer like the spacer pattern 25.

Referring to FIG. 2F, a pattern 22A is formed by etching the etch stop layer 23 and the etch target layer 22 using the partially etched first and the second hard mask patterns 24A and 26A as an etch barrier.

A reference numeral 23A represents an etched etch stop layer.

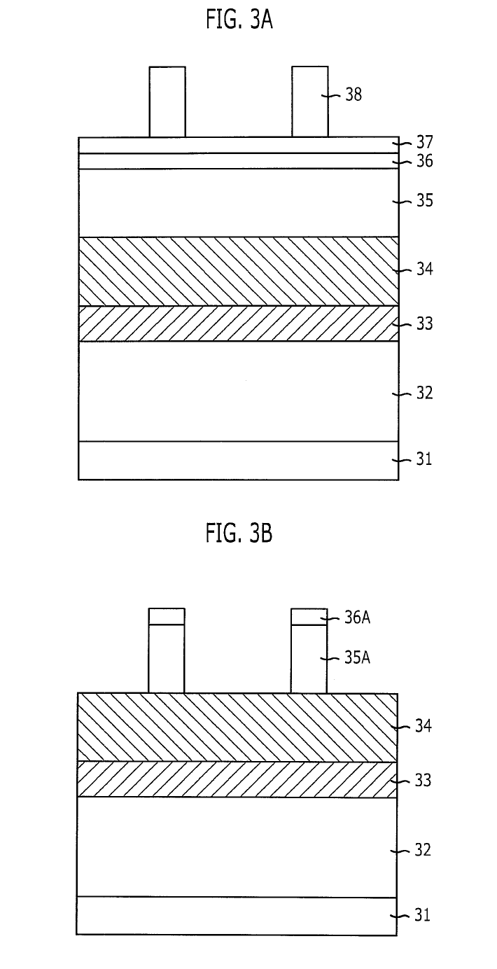

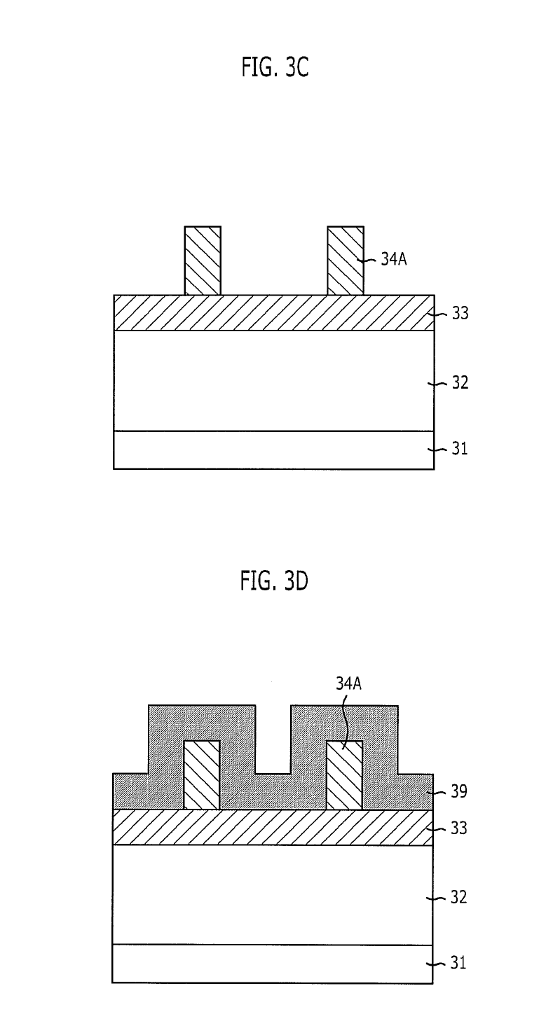

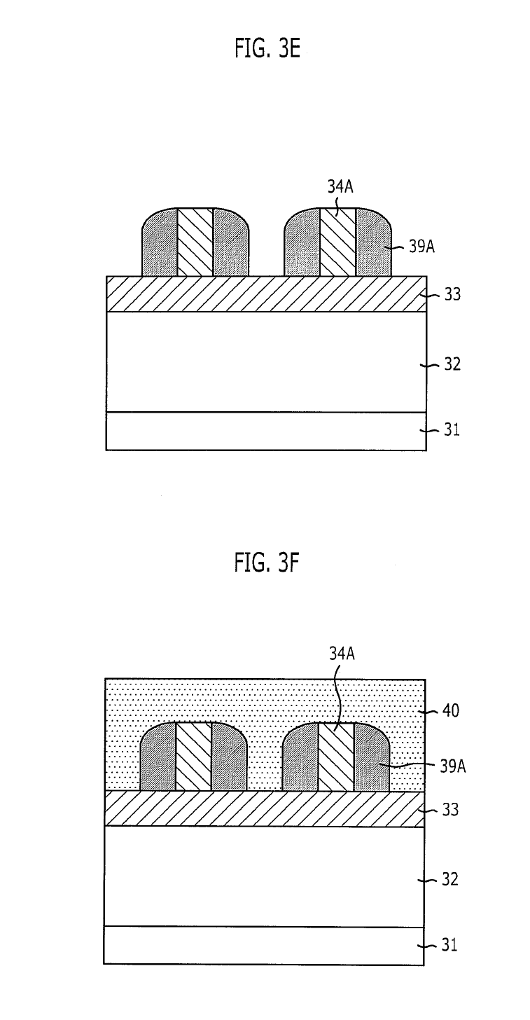

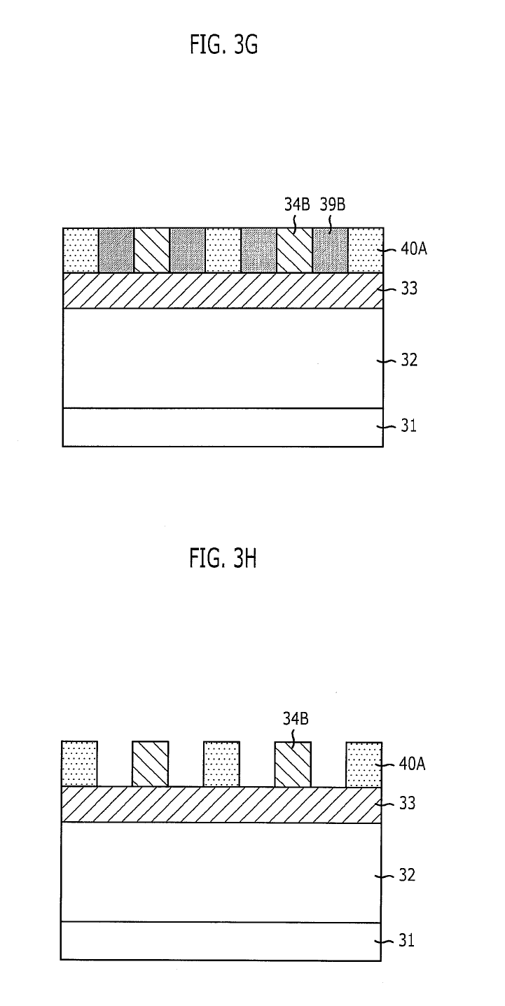

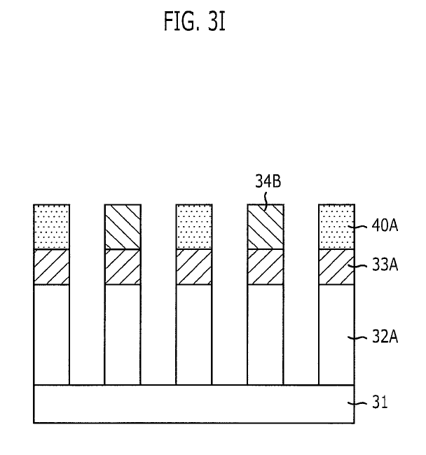

FIGS. 3A to 3I illustrate cross-sectional views of a method for fabricating a semiconductor device in accordance with a detailed embodiment of the present invention.

Referring to FIG. 3A, an etch target layer 32 is formed on a substrate 31. The substrate 31 may include a silicon substrate employed when fabricating a DRAM device or a nonvolatile memory device. The etch target layer 32 is a layer where a pattern is to be formed through a subsequent SPT process and may include an oxide layer. Here, the oxide layer may include a TEOS oxide layer, especially a PE-TEOS oxide layer.

Then, an etch stop layer 33 is formed on the etch target layer 32. The etch stop layer 33 is provided to prevent the loss of the etch target layer 32 and may be formed of a material having selectivity to a subsequent first hard mask pattern. The etch stop layer 33 may include a nitride layer. Further, the etch stop layer 33 is formed to have a thickness that is required to sufficiently perform an etch stop function in a subsequent process. For instance, the etch stop layer 33 may have a thickness of approximately 20 Å to approximately 500 Å.

A first hard mask layer 34 is formed on the etch stop layer 33. The first hard mask layer 34 is used as an etch barrier in a subsequent process of forming patterns. Therefore, the first hard mask layer 34 may be formed of a material having selectivity to the etch target layer 32 and the etch stop layer 33 and include a polysilicon layer.

Subsequently, a second hard mask layer 35 is formed on the first hard mask layer 34. The second hard mask layer 35 is provided to etch the first hard mask layer 34 and may be formed of a material having selectivity to the first hard mask layer 34. The second hard mask layer 35 is formed of a carbon series material and the carbon series material includes amorphous carbon.

A silicon oxynitride (SiON) layer 36 and an anti-reflection layer 37 are formed on the second hard mask layer 35. The silicon oxynitride layer 36 serves as an etch barrier to etch the second hard mask layer 35 and performs an anti-reflection function together with the anti-reflection layer 37 when forming a subsequent photoresist pattern 38. The anti-reflection layer 37 serves as a layer for preventing the reflection when forming the photoresist pattern 38.

The photoresist pattern 38 is formed on the anti-reflection layer 37. The photoresist pattern 38 is provided to primarily form a hard mask pattern. Therefore, since a gap between patterns is wide, the photoresist pattern 38 is easily formed without being limited by the resolution in an exposure process thereof.

Referring to FIG. 3B, the anti-reflection layer 37 and the silicon oxynitride layer 36 are etched using the photoresist pattern 38 as an etch barrier. After then, a second hard mask pattern 35A is formed by etching the second hard mask layer 35 using the etched silicon oxynitride layer 36A as an etch barrier.

Referring to FIG. 3C, a first hard mask pattern 34A is formed by etching the first hard mask layer 34 using the second hard mask pattern 35A as an etch barrier.

After forming the first hard mask pattern 34A, the second hard mask pattern 35A is removed. In case the second hard mask pattern 35A includes the amorphous carbon, the second hard mask pattern 35A is easily removed through an oxygen strip process.

Referring to FIG. 3D, a spacer layer 39 is formed over a resultant structure including the first hard mask pattern 34A. The spacer layer 39 includes an oxide layer and the oxide layer includes a TEOS oxide layer. Further, the TEOS oxide layer includes a LP-TEOS oxide layer.

Referring to FIG. 3E, a spacer pattern 39A is formed on a sidewall of the first hard mask pattern 34A by etching the spacer layer 39.

In case the spacer layer 39 is formed of the oxide layer, the etching process of forming the spacer pattern 39A may be performed using a gas for etching the oxide layer, especially an oxygen gas and one selected from a group comprising C₄F₈, CHF₃, CH₂F₂, C₄F₆ and a combination thereof. Further, each gas may be added with a flow of approximately 4 sccm to approximately 500 sccm. The etching process of forming the spacer pattern 39A may be performed for approximately 10 seconds to approximately 100 seconds.

Therefore, the loss of the etch target layer 32 is prevented by the etch stop layer 33 including the nitride layer when forming the spacer pattern 39A including the oxide layer.

Referring to FIG. 3F, a third hard mask layer 40 is formed on an entire surface of a resultant structure including the spacer pattern 39A. The third hard mask layer 40 serves as an etch barrier together with the first hard mask pattern 34A in a subsequent process of forming patterns. The third hard mask layer 40 may be formed of the same material as that of the first hard mask pattern 34A. That is, the third hard mask layer 40 may include a polysilicon layer.

The third hard mask layer 40 may be formed to have a thickness greater than a height of the spacer pattern 39A to sufficiently fill spaces between neighboring spacer patterns 39A.

Referring to FIG. 3G, a third hard mask pattern 40A is formed by etching or polishing the third hard mask layer 40 up to the same height as that of the first hard mask pattern 34A.

In order to form the third hard mask pattern 40A, it is preferable to perform an etch-back process or a chemical mechanical polishing (CMP) process.

Particularly, the third hard mask pattern 40A has the same height as that of the first hard mask pattern 34A. The third hard mask pattern 40A has a vertical profile. That is, in case the spacer pattern 39A has an inclined profile at its top surface by the etching process, the third hard mask pattern 40A having the vertical profile is formed by additionally etching the third hard mask layer 40 buried in a plane that corresponds to the inclined profile (for example, etching the vertical space where the inclined profile is located). When forming the third hard mask pattern 40A, upper portions of the first hard mask pattern 34A and the spacer pattern 39A may be partially etched up to a top surface of the third hard mask pattern 40A.

Accordingly, the partially etched first and the third hard mask patterns 34B and 40A and the partially etched spacer pattern 39B have a vertical profile.

When forming the third hard mask pattern 40A, since the spacer pattern 39A is formed on the sidewall of the first hard mask pattern 34A and the first hard mask pattern 34A disposed between neighboring spacer patterns 39A is exposed, only the third hard mask layer 40 is additionally etched or there does not occur a height difference between the first and the third hard mask patterns 34A and 40A. Therefore, the variation in critical dimensions of neighboring patterns caused by the height difference is improved.

Moreover, since there is no height difference, the etch target layer 32 is not required to be further etched in FIG. 3C and the loss of the etch target layer 32 is prevented by forming the etch stop layer 33 on the etch target layer 32.

Referring to FIG. 3H, the partially etched spacer pattern 39B disposed between the partially etched first and the third hard mask patterns 34B and 40A is removed. The partially etched spacer pattern 39B may be removed through a wet etching process. In case the spacer pattern 39A includes the oxide layer, the wet etching process may be performed using a BOE or HF.

Therefore, the partially etched first and the third hard mask patterns 34B and 40A remain as being separated from each other as much as a width of the partially etched spacer pattern 39B.

Since the partially etched spacer pattern 39B is removed through the wet etching process not a dry etching process, the loss of underlying layers is prevented. Furthermore, by forming the etch stop layer 33 having selectivity on the etch target layer 32 formed of the oxide layer like the spacer pattern 39A, the loss of the etch target layer 32 is prevented when removing the partially etched spacer pattern 39B.

Referring to FIG. 3I, a pattern 32A is formed by etching the etch stop layer 33 and the etch target layer 32 using the partially etched first and the third hard mask patterns 34B and 40A as an etch barrier.

A reference numeral 33A represents an etched etch stop layer.

In accordance with the embodiments of the present invention, since a subsequent process is performed after forming the spacer pattern on the sidewall of the hard mask pattern, there does not occur a height difference between neighboring hard mask patterns.

Accordingly, the variation in critical dimensions of neighboring patterns caused by the height difference is improved.

Further, the additional etching of the etch target layer for the height difference is not required and the deterioration of the device characteristic according to the additional etching is prevented.

The loss of the etch target layer is prevented in the subsequent process by forming the etch stop layer on the etch target layer.

Moreover, since the spacer pattern is removed using the wet etching process not the dry etching process, the fabricating process is simplified and the loss of its underlying layers is prevented.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, the method comprising:
forming an etch stop layer over an etch target layer;
forming a first hard mask pattern over the etch stop layer;
forming a spacer pattern over a sidewall of the first hard mask pattern;
forming a second hard mask layer over an entire surface of a resultant structure including the spacer pattern;
forming a second hard mask pattern by etching the second hard mask layer up to a height of the first hard mask pattern;
removing the spacer pattern; and
forming a pattern by etching the etch stop layer and the etch target layer using the first and the second hard mask patterns as an etch barrier.

2. The method of claim 1, wherein the first and the second hard mask patterns are formed of the same material.

3. The method of claim 2, wherein the first and the second hard mask patterns include polysilicon.

4. The method of claim 2, wherein the etch stop layer is formed of a material having selectivity to the first hard mask pattern.

5. The method of claim 4, wherein the etch stop layer comprises a nitride layer.

6. The method of claim 1, wherein the spacer pattern comprises an oxide layer.

7. The method of claim 1, wherein the forming of the spacer pattern comprises:
forming a spacer layer along a top surface of a resultant structure including the first hard mask pattern; and
etching the spacer layer to thereby form the spacer pattern.

8. The method of claim 7, wherein the etching of the spacer layer is performed using an oxygen gas and one selected from a group consisting of C₄F₈, CHF₃, CH₂F₂, C₄F₆ and a combination thereof.

9. A method for fabricating a semiconductor device, the method comprising:
forming an etch stop layer and a first hard mask layer over an etch target layer;
forming a second hard mask pattern over the first hard mask layer;
forming a first hard mask pattern by etching the first hard mask layer using the second hard mask pattern as an etch barrier;
forming a spacer layer along a top surface of a resultant structure including the first hard mask pattern;
forming a spacer pattern on a sidewall of the first hard mask pattern by etching the spacer layer;
forming a third hard mask layer on an entire surface of a resultant structure including the spacer pattern;
forming a third hard mask pattern by etching the third hard mask layer up to a height of the first hard mask pattern;
removing the spacer pattern; and
forming a pattern by etching the etch stop layer and the etch target layer using the first and the third hard mask patterns as an etch barrier.

10. The method of claim 9, wherein the first and the third hard mask patterns are formed of the same material.

11. The method of claim 10, wherein the first and the third hard mask patterns include polysilicon.

12. The method of claim 10, wherein the etch stop layer is formed of a material having selectivity to the first hard mask pattern.

13. The method of claim 12, wherein the etch stop layer comprises a nitride layer.

14. The method of claim 10, wherein the second hard mask layer is formed of a material having selectivity to the first hard mask pattern.

15. The method of claim 14, wherein the second hard mask layer comprises amorphous carbon.

16. The method of claim 9, wherein the spacer layer comprises an oxide layer.

17. The method of claim 9, wherein the forming of the spacer pattern is performed using an oxygen gas and one selected from a group consisting of C₄F₈, CHF₃, CH₂F₂, C₄F₆ and a combination thereof.
